(19) United States
(12) Patent Application Publication
(10) Pub. No.: US 2026/0247984 A1
(43) Pub. Date: Aug. 20, 2026

(54) SEMICONDUCTOR PACKAGE

(71) Applicant: Samsung Electronics Co., Ltd., Suwon-si (KR)

(72) Inventors: Choongbin Yim, Suwon-si (KR); Jongkook Kim, Suwon-si (KR)

(21) Appl. No.: 19/352,143

(22) Filed: Oct. 7, 2025

(30) Foreign Application Priority Data
Feb. 18, 2025 (KR) 10-2025-0020903

(51) Int. Cl. H10W 44/00; H10B 80/00; H10D 80/30; H10W 70/60; H10W 90/00; H10W 74/15; H10W 90/26

(52) U.S. Cl. CPC H10W 44/601; H10B 80/00; H10D 80/30; H10W 70/611; H10W 90/00; H10W 90/401; H10W 74/15; H10W 90/26; H10W 90/721; H10W 90/724; H10W 90/734; H10W 90/794

(57) ABSTRACT

A semiconductor package comprises a base substrate and a first chip, a second chip, and an interposer electrically connected to the base substrate. The first chip, the second chip, and the interposer overlap with each other. The interposer is disposed between the first chip and the second chip. The interposer comprises a capacitor structure electrically connected to the first chip.

### CROSS-REFERENCE TO RELATED APPLICATIONS

This U.S. non-provisional patent application claims priority under 35 U.S.C. §119 to Korean Patent Application No. 10-2025-0020903, filed on February 18, 2025, in the Korean Intellectual Property Office, the entire contents of which are hereby incorporated by reference.

### BACKGROUND

A semiconductor package is a structure comprising integrated circuit chips suitable for use in electronics. Typically, the semiconductor package comprises semiconductor chips on a printed circuit board and electrically connect them using bonding wires or bumps. Various studies for improving the reliability of semiconductor packages have been conducted.

### SUMMARY

In general, the present disclosure is directed toward a semiconductor package having an interposer, which includes a capacitor, between a logic chips.

According to some implementations, the present disclosure is directed to a semiconductor pack that comprises a base substrate; and a first chip, a second chip, and an interposer electrically connected to the base substrate. The first chip, the second chip, and the interposer overlap with each other. The interposer is disposed between the first chip and the second chip. The interposer comprises a capacitor structure electrically connected to the first chip.

According to some implementations, the present disclosure is directed to a semiconductor package that comprises a base substrate; and a first chip, a second chip, and an interposer electrically connected to the base substrate. The first chip, the second chip, and the interposer overlap with each other. The interposer is disposed between the first chip and the second chip. The second chip is disposed between the base substrate and the interposer. The interposer comprises a first substrate and a first capacitor structure. The first capacitor structure is disposed between the first substrate and the first chip.

According to some implementations, the present disclosure is directed to a semiconductor package that comprises a package substrate; a base substrate electrically connected to the package substrate; and a first chip, a second chip, an interposer, first memory chips and second memory chips electrically connected to the base substrate. The first chip, the second chip, and the interposer overlap with each other. The first memory chips overlap with each other. The second memory chips overlap with each other. The interposer is disposed between the first chip and the second chip. The first chip, the second chip, and the interposer are disposed between the first memory chips and the second memory chips. The interposer comprises a substrate and a through via penetrating the substrate. The first chip comprises a first logic cell structure. The second chip comprises a second logic cell structure. The through via electrically connects the first chip and the second chip.

According to some implementations, the present disclosure is directed to a method of fabricating a semiconductor package that comprises forming a first chip on a carrier substrate; electrically connecting an interposer to the first chip; electrically connecting a second chip to the interposer; and mounting the first chip, the second chip, and the interposer to a base substrate. The interposer comprises a capacitor structure electrically connected to the first chip.

According to some implementations, the present disclosure is directed to a method of fabricating a semiconductor package that includes electrically connecting the interposer to the first chip may comprise hybrid bonding the first chip and the interposer.

According to some implementations, the present disclosure is directed to a method of fabricating a semiconductor package that includes electrically connecting the second chip to the interposer may comprise hybrid bonding the interposer and the second chip.

According to some implementations, the present disclosure is directed to a method of fabricating a semiconductor package that includes mounting the base substrate on a package substrate.

According to some implementations, the present disclosure is directed to a method of fabricating a semiconductor package that includes mounting memory chips on the base substrate.

### BRIEF DESCRIPTION OF THE DRAWINGS

Example implementations will be more clearly understood from the following explanation, taken in conjunction with the accompanying drawings.

FIG. 1A is a cross-sectional view of an example of a semiconductor package according to some implementations.

FIG. 1B is an enlarged view of an example of a Q1 region of FIG. 1A according to some implementations.

FIG. 1C is an enlarged view of an example of a Q2 region of FIG. 1A according to some implementations.

FIGS. 2, 3, 4, 5, 6, 7, 8 and 9 are cross-sectional views illustrating an example of a method of fabricating a semiconductor package according to some implementations.

FIG. 10 is an enlarged view of an example of a semiconductor package according to some implementations.

### DETAILED DESCRIPTION

Hereinafter, example implementations will be explained in detail with reference to the accompanying drawings.

In some implementations, the present disclosure is directed to a capacitor structure disposed within an interposer, in which a logic cell structure may be supplied with power from the capacitor structure within the interposer. Accordingly, the power supply path may be relatively short, and the voltage (IR) drop may be reduced.

In some implementations, the present disclosure is directed to a capacitor structure disposed in a base substrate, such that a logic cell structure is powered from the capacitor structure in the base substrate. Accordingly, the power supply path may be relatively short, and the IR drop may be reduced.

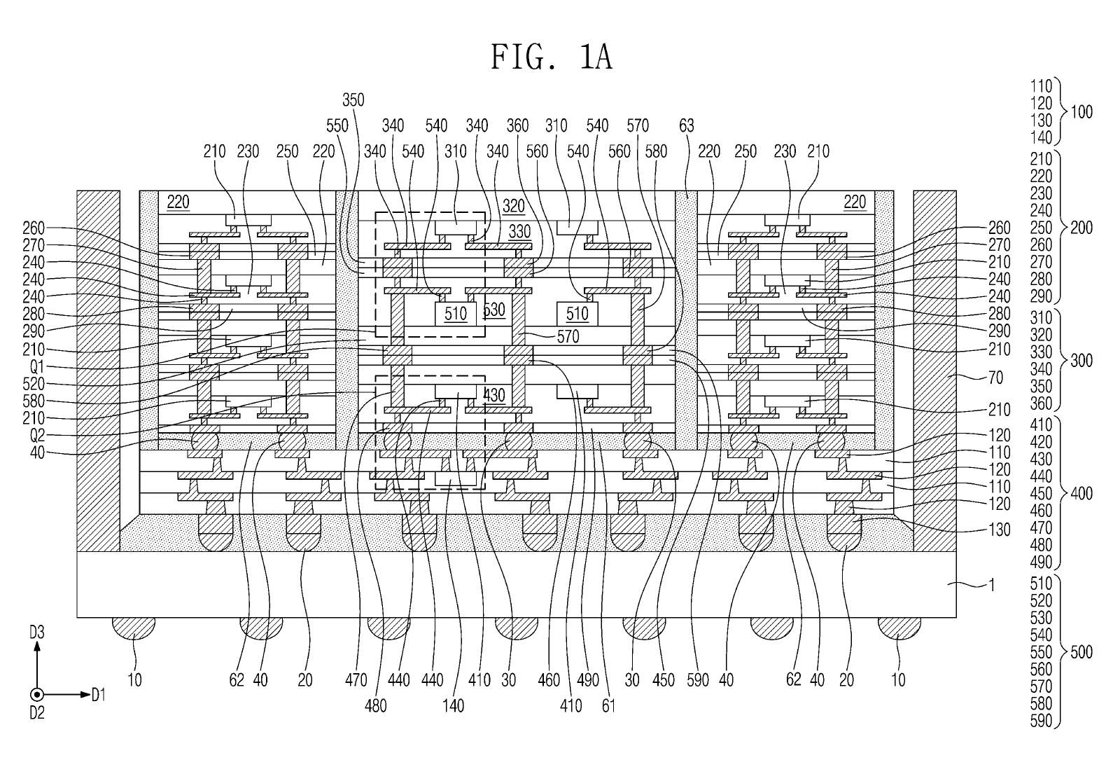

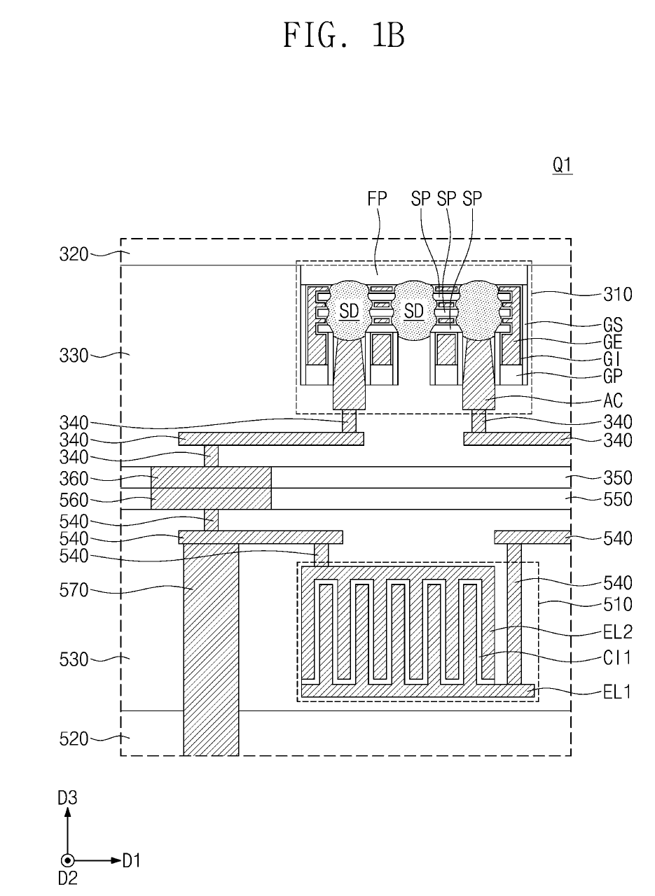

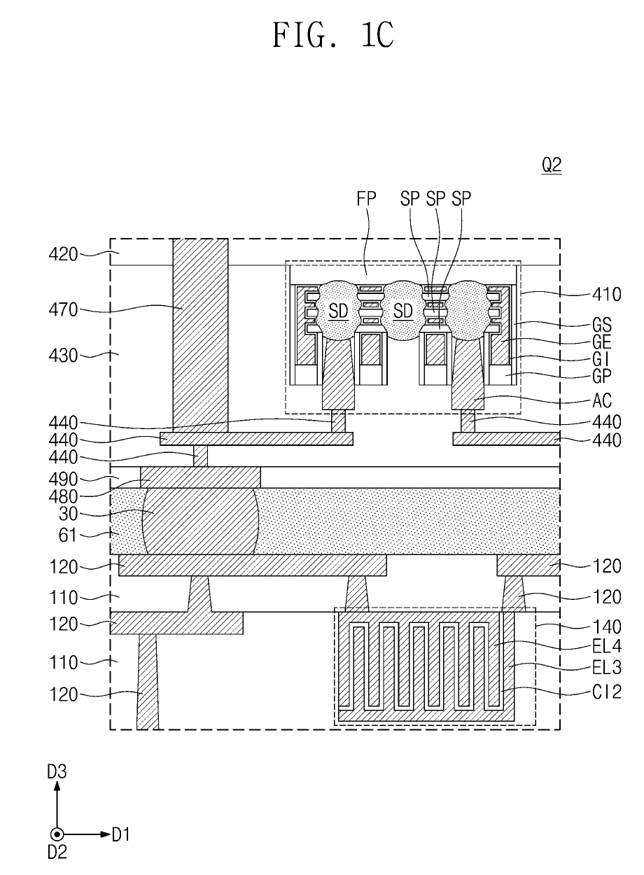

FIG. 1A is a cross-sectional view of an example of a semiconductor package according to some implementations. FIG. 1B is an enlarged view of a Q1 region of FIG. 1A. FIG. 1C is an enlarged view of a Q2 region of FIG. 1A.

In FIG. 1A, a semiconductor package may include a terminal 10, a package substrate 1, a first bump 20, a second bump 30, a third bump 40, a base substrate 100, memory chips 200, a first chip 300, a second chip 400, an interposer 500, a first underfill layer 50, a second underfill layer 61, a third underfill layer 62, a molding layer 63, and a heat slug 70.

The package substrate 1 may have the shape of a plate extending along a plane defined by a first direction D1 and a second direction D2. The first direction D1 and the second direction D2 may intersect with each other. As an example, the first direction D1 and the second direction D2 may be horizontal directions orthogonal to each other. The package substrate 1 may be, for example, a printed circuit board (PCB) or a redistribution substrate.

The terminals 10 may be connected to the package substrate 1. The terminals 10 may include a conductive material.

The base substrate 100 may be mounted on the package substrate 1. The base substrate 100 may be electrically connected to the package substrate 1. The first bump 20 may be provided between the base substrate 100 and the package substrate 1. The first bump 20 may comprise a conductive material. The first underfill layer 50 may be provided between the base substrate 100 and the package substrate 1. The first underfill layer 50 may include a polymer material.

The base substrate 100 may include a redistribution pattern 120, a photosensitive insulating layer 110, and a bump connection pattern 130. The photosensitive insulating layers 110 may be sequentially stacked along a third direction D3. The third direction D3 may intersect with the first direction D1 and the second direction D2. As an example, the third direction D3 may be a vertical direction orthogonal to the first direction D1 and the second direction D2.

The photosensitive insulating layers 110 may include a photo-imageable dielectric (PID) material. The photosensitive dielectric material may include, for example, at least one of a photosensitive polyimide, a polybenzoxazole, a phenol-based polymer, and a benzocyclobutene-based polymer.

The redistribution pattern 120 may be surrounded by the photosensitive insulating layers 110. The redistribution pattern 120 may be disposed in the photosensitive insulating layers 110. At least some of the redistribution patterns 120 may include a base portion and a via portion on the base portion. The width of the base portion may be greater than the width of the via portion. The base portion may have the shape of a line or a bar, and the via portion may have the shape of a pillar.

The redistribution patterns 120 may include a conductive material. In one example, the redistribution patterns 120 may include copper.

The bump connection pattern 130 may be connected to the redistribution pattern 120. The bump connection pattern 130 may be disposed on the outside of the photosensitive insulating layers 110. The bump connection pattern 130 may include a conductive material. In one example, the bump connection pattern 130 may include copper.

In some implementations, the base substrate 100 may be an interposer including a semiconductor substrate and through vias penetrating the semiconductor substrate. In some implementations, the base substrate 100 may be a printed circuit board.

The memory chips 200, the first chip 300, the second chip 400, and the interposer 500 may be electrically connected to the base substrate 100. The memory chips 200, the first chip 300, the second chip 400, and the interposer 500 may overlap with the base substrate 100 in the third direction D3. The first chip 300, the second chip 400, and the interposer 500 may overlap with each other in the third direction D3.

The interposer 500 may be disposed between the first chip 300 and the second chip 400. The interposer 500 may be disposed at a lower level than the first chip 300 and may be disposed at a higher level than the second chip 400.

The second chip 400 and the interposer 500 may be disposed between the first chip 300 and the base substrate 100. The second chip 400 may be disposed between the interposer 500 and the base substrate 100. The second chip 400 may be disposed at a higher level than the base substrate 100.

The first and second chips 300, 400 may be logic chips. For example, the first and second chips 300, 400 may be a central processing unit (CPU), a graphics processing unit (GPU), or an application processor (AP).

The first chip 300 may include a first substrate 320, a first insulating structure 330, a first conductive structure 340, a first lower insulating layer 350, a first lower pad 360, and a first logic cell structure 310.

The first substrate 320 may be a semiconductor substrate, an insulator substrate, or a semiconductor-on-insulator (SOI) substrate. The semiconductor substrate may comprise, for example, silicon, germanium, silicon-germanium, GaP or GaAs.

The first logic cell structure 310 may be disposed on a lower surface of the first substrate 320.

The first conductive structure 340 may be electrically connected to the first logic cell structure 310. The first conductive structure 340 may include at least one of a conductive via, a conductive line, or a conductive pad. The first conductive structure 340 may include a conductive material.

The first insulating structure 330 may surround the first conductive structures 340. The first conductive structure 340 may be disposed in the first insulating structure 330. The first insulating structure 330 may be disposed on a lower surface of the first substrate 320. The first insulating structure 330 may include an insulating material. In some implementations, the first insulating structure 330 may be a multiple layer including a plurality of insulating layers.

The first lower pad 360 may be electrically connected to the first conductive structure 340. The first lower pad 360 may be in contact with the first conductive structure 340. The first logic cell structure 310 may be electrically connected to the first lower pad 360 through the first conductive structure 340. The first lower pad 360 may include a conductive material.

The first lower insulating layer 350 may surround the first lower pad 360. The first lower pad 360 may be disposed in the first lower insulating layer 350. The first lower insulating layer 350 may include an insulating material. In some implementations, the first lower insulating layer 350 may be a multiple layer including a plurality of insulating layers.

The second chip 400 may include a second substrate 420, a second insulating structure 430, a second conductive structure 440, a first upper insulating layer 450, a first upper pad 460, a first through via 470, a second lower pad 480, a second lower insulating layer 490, and a second logic cell structure 410.

The second substrate 420 may be a semiconductor substrate, an insulator substrate, or a semiconductor-on-insulator (SOI) substrate.

The second logic cell structure 410 may be disposed on a lower surface of the second substrate 420.

The second conductive structure 440 may be electrically connected to the second logic cell structure 410. The second conductive structure 440 may include at least one of a conductive via, a conductive line, or a conductive pad. The second conductive structure 440 may include a conductive material.

The second insulating structure 430 may surround the second conductive structures 440. The second conductive structures 440 may be disposed within the second insulating structure 430. The second insulating structure 430 may be disposed on a lower surface of the second substrate 420. The second insulating structure 430 may include an insulating material. In some implementations, the second insulating structure 430 may be a multiple layer including a plurality of insulating layers.

The second lower pad 480 may be electrically connected to the second conductive structure 440. The second lower pad 480 may be in contact with the second conductive structure 440. The second logic cell structure 410 may be electrically connected to the second lower pad 480 through second conductive structures 440. The second lower pad 480 may include a conductive material.

The second lower insulating layer 490 may surround the second lower pad 480. The second lower pad 480 may be disposed in a second lower insulating layer 490. The second lower insulating layer 490 may include an insulating material. In some implementations, the second lower insulating layer 490 may be a multiple layer including a plurality of insulating layers.

The first through via 470 may be electrically connected to the second conductive structure 440. The first through via 470 may be in contact with the second conductive structure 440. The first through via 470 may penetrate the second substrate 420 in the third direction D3. The first through via 470 may include a conductive material.

The first upper pad 460 may be electrically connected to the first through via 470. The first upper pad 460 may be in contact with the first through via 470. The second logic cell structure 410 may be electrically connected to the first upper pad 460 through the second conductive structure 440 and the first through via 470. The first upper pad 460 may include a conductive material.

The first upper insulating layer 450 may surround the first upper pad 460. The first upper pad 460 may be disposed in the first upper insulating layer 450. The first upper insulating layer 450 may include an insulating material. In some implementations, the first upper insulating layer 450 may be a multiple layer including a plurality of insulating layers.

The interposer 500 may include a third substrate 520, a third insulating structure 530, a third conductive structure 540, a second upper insulating layer 550, a second upper pad 560, a second through via 570, a third lower pad 580, a third lower insulating layer 590, and a first capacitor structure 510. The interposer 500 may not include a transistor.

The third substrate 520 may be a semiconductor substrate, an insulator substrate, or a semiconductor-on-insulator (SOI) substrate.

The third conductive structure 540 may be electrically connected to the first capacitor structure 510. The third conductive structures 540 may include at least one of a conductive via, a conductive line, or a conductive pad. The third conductive structures 540 may include a conductive material.

The third insulating structure 530 may surround the third conductive structure 540. The third conductive structure 540 may be disposed within the third insulating structure 530. The third insulating structure 530 may be disposed on an upper surface of the third substrate 520. The third insulating structure 530 may include an insulating material. In some implementations, the third insulating structure 530 may be a multi-layer including a plurality of insulating layers.

The second upper pad 560 may be electrically connected to the third conductive structure 540. The second upper pad 560 may be in contact with the third conductive structure 540. The first capacitor structure 510 may be electrically connected to the second upper pad 560 through third conductive structures 540. The second upper pad 560 may include a conductive material.

The second upper insulating layer 550 may surround the second upper pad 560. The second upper pad 560 may be disposed in the second upper insulating layer 550. The second upper insulating layer 550 may include an insulating material. In some implementations, the second upper insulating layer 550 may be a multiple layer including a plurality of insulating layers.

The second through via 570 may be electrically connected to the third conductive structure 540. The second through via 570 may be in contact with the third conductive structure 540. The second through via 570 may penetrate the third substrate 520 in the third direction D3. The second through via 570 may include a conductive material.

The third lower pad 580 may be electrically connected to the second through via 570. The third lower pad 580 may be in contact with the second through via 570. The first capacitor structure 510 may be electrically connected to the third lower pad 580 through the third conductive structure 540 and the second through via 570. The third lower pad 580 may include a conductive material.

The third lower insulating layer 590 may surround the third lower pad 580. The third lower pad 580 may be disposed in the third lower insulating layer 590. The third lower insulating layer 590 may include an insulating material. In some implementations, the third lower insulating layer 590 may be a multiple layer including a plurality of insulating layers.

The first logic cell structure 310, the first insulating structure 330, the first conductive structure 340, the first lower insulating layer 350, the first lower pad 360, the second upper pad 560, the second upper insulating layer 550, the third conductive structure 540, the third insulating structure 530, and the first capacitor structure 510 may be disposed between the first substrate 320 and the third substrate 520.

The first logic cell structure 310, the first insulating structure 330, the first conductive structure 340, the first lower insulating layer 350, the first lower pad 360, the second upper pad 560, the second upper insulating layer 550, the third conductive structure 540, the third insulating structure 530, and the first capacitor structure 510 may be disposed at a lower level than the first substrate 320, and may be disposed at a higher level than the third substrate 520.

The first logic cell structure 310, the first insulating structure 330, the first conductive structure 340, the first lower insulating layer 350, and the first lower pad 360 may be disposed between the first substrate 320 and the interposer 500.

The second upper pad 560, the second upper insulating layer 550, the third conductive structure 540, the third insulating structure 530, and the first capacitor structure 510 may be disposed between the first chip 300 and the third substrate 520.

The first lower pad 360 may be in contact with the second upper pad 560. The first logic cell structure 310 may be electrically connected to the first capacitor structure 510 through the first conductive structure 340, the first lower pad 360, the second upper pad 560, and the third conductive structure 540. The first capacitor structure 510 may be electrically connected to the first chip 300 through the second upper pad 560 and the third conductive structure 540.

The third lower pad 580 may be in contact with the first upper pad 460. The first lower insulating layer 350 may be in contact with the second upper insulating layer 550. The third lower insulating layer 590 may be in contact with the first upper insulating layer 450.

A lower surface of the first chip 300 may be hybrid-bonded to an upper surface of the interposer 500. The upper surface of the second chip 400 may be hybrid-bonded to the lower surface of the interposer 500.

The second bump 30 may be provided between the second chip 400 and the base substrate 100. The second bump 30 may comprise a conductive material. The second underfill layer 61 may be provided between the second chip 400 and the base substrate 100. The second underfill layer 61 may include a polymer material.

The base substrate 100 may further include a second capacitor structure 140. The second capacitor structure 140 may be electrically connected to the redistribution pattern 120. The second capacitor structure 140 may be electrically connected to the second bump 30 through the redistribution pattern 120. The second capacitor structure 140 may be disposed in the photosensitive insulating layers 110. The second capacitor structure 140 may be surrounded by the photosensitive insulating layers 110.

The second logic cell structures 410, the second lower pad 480, the second insulating structure 430, the second conductive structure 440, the second lower insulating layer 490, and the second bump 30 may be disposed between the second substrate 420 and the base substrate 100.

The second logic cell structure 410, the second lower pad 480, the second insulating structure 430, the second conductive structure 440, the second lower insulating layer 490, and the second bump 30 may be disposed at a lower level than the second substrate 420, and may be disposed at a higher level than the base substrate 100.

The second bump 30 may be in contact with the second lower pad 480 and the redistribution pattern 120. The second logic cell structure 410 may be electrically connected to the second capacitor structure 140 through the second conductive structure 440, the second lower pad 480, the second bump 30, and the redistribution pattern 120. The second capacitor structure 140 may be electrically connected to the second chip 400 through the redistribution pattern 120 and the second bump 30.

The memory chips 200 may include first memory chips that overlap with each other in the third direction D3 and second memory chips that overlapping with each other in a third direction D3. The first chip 300, the second chip 400, and the interposer 500 may be disposed between the first memory chips and the second memory chips.

The memory chips 200 may be a volatile memory chip or a non-volatile memory chip. The volatile memory chip may be, for example, dynamic random access memory (DRAM), static RAM (SRAM), thyristor RAM (TRAM), zero capacitor RAM (ZRAM), or Twin Transistor RAM (TTRAM). The non-volatile memory chip may be, for example, flash memory, magnetic RAM (MRAM), spin-transfer torque MRAM (STT-MRAM), ferroelectric RAM (FRAM), phase change RAM (PRAM), resistive RAM (RRAM), polymer RAM, or insulator resistance change memory.

Each of the memory chips 200 may include a memory substrate 220, a memory insulating structure 230, a memory conductive structure 240, a memory upper insulating layer 250, a memory upper pad 260, a memory through via 270, a memory lower pad 280, a memory lower insulating layer 290, and a memory cell structure 210. Uppermost one of the memory chips 200 may not include the memory upper insulating layer 250, the memory upper pad 260, and the memory through via 270.

The memory substrate 220 may be a semiconductor substrate, an insulator substrate, or a semiconductor-on-insulator (SOI) substrate.

The memory cell structure 210 may be disposed on a lower surface of the memory substrate 220.

The memory conductive structure 240 may be electrically connected to the memory cell structure 210. The memory conductive structure 240 may include at least one of a conductive via, a conductive line, or a conductive pad. The memory conductive structure 240 may include a conductive material.

The memory insulating structure 230 may surround the memory conductive structure 240. The memory conductive structure 240 may be disposed in the memory insulating structure 230. The memory insulating structure 230 may be disposed on a lower surface of the memory substrate 220. The memory insulating structure 230 may include an insulating material. In some implementations, the memory insulating structure 230 may be a multi-layer including a plurality of insulating layers.

The memory lower pad 280 may include a conductive material. The memory lower insulating layer 290 may surround the memory lower pad 280. The memory lower insulating layer 290 may include an insulating material.

The memory through via 270 may penetrate (or extend into) the memory substrate 220 in the third direction D3. The memory through via 270 may include a conductive material.

The memory upper pad 260 may include a conductive material. The memory upper insulating layer 250 may surround the memory upper pad 260. The memory upper insulating layer 250 may include an insulating material.

The memory upper pad 260 and the memory lower pad 280 may be in contact with each other. The memory upper insulating layer 250 and the memory lower insulating layer 290 may be in contact with each other. The memory chips 200 may be hybrid-bonded to each other.

The third bump 40 may be provided between the memory chips 200 and the base substrate 100. The third bump 40 may comprise a conductive material. The third underfill layer 62 may be provided between the memory chips 200 and the base substrate 100. The third underfill layer 62 may include a polymer material.

The molding layer 63 surrounding the memory chips 200, the first chip 300, the second chip 400, and the interposer 500 may be provided. The molding layer 63 may include a polymer material.

The heat slug 70 may be provided on the package substrate 1. In some implementations, the heat slug 70 may have the shape of a ring surrounding the base substrate 100, the memory chips 200, the first chip 300, the second chip 400, and the interposer 500. The heat slug 70 may release heat generated in the base substrate 100, the memory chips 200, the first chip 300, the second chip 400, and the interposer 500 to the outside.

In FIG. 1B, the first logic cell structure 310 may include a fin pattern FP, semiconductor patterns SP, source/drain patterns SD, a gate electrode GE, a gate spacer GS, a gate insulating layer GI, a gate capping pattern GP, and an active contact AC.

The fin pattern FP, the semiconductor patterns SP, the source/drain patterns SD, the gate electrode GE, the gate spacer GS, the gate insulating layer GI, the gate capping pattern GP and the active contact AC of the first logic cell structure 310 may be surrounded by the first insulating structure 330.

The fin pattern FP may be part of the first substrate 320. A portion of the first substrate 320 protruding in a direction opposite to the third direction D3 may be defined as the fin pattern FP.

The source/drain patterns SD may be connected to the fin pattern FP. The source/drain patterns SD may be an epitaxial pattern formed with a Selective Epitaxial Growth (SEG) process. The source/drain patterns SD may comprise a semiconductor material. As an example, the source/drain patterns SD may include at least one of silicon (Si), silicon-germanium (SiGe), or germanium (Ge). The source/drain patterns SD may be doped with dopants.

The semiconductor pattern SP may be connected to the source/drain patterns SD. The semiconductor patterns SP between the source/drain patterns SD adjacent to each other may overlap with each other in the third direction D3. In some implementations, the semiconductor patterns SP may comprise silicon (Si). For example, the semiconductor patterns SP may comprise crystalline silicon. In some implementations, the semiconductor patterns SP may include silicon-germanium (SiGe).

The gate electrode GE may overlap with the semiconductor pattern SP in the third direction D3. The gate electrode GE may include portions provided between the semiconductor patterns SP. A gate electrode GE and the semiconductor patterns SP may constitute a three-dimensional field effect transistor (e.g., an MBCFET or a GAAFET). The gate electrode GE may include a conductive material.

The gate insulating layer GI may be provided. The gate insulating layer GI may be in contact with the gate electrode GE, the semiconductor patterns SP, and the source/drain patterns SD. The gate insulating layer GI may separate the gate electrode GE from the semiconductor pattern SP and the source/drain patterns SD. The gate insulating layer GI may include an insulating material. As an example, the gate insulating layer GI may include silicon oxide.

The gate spacers GS may be provided. A pair of the gate spacers GS may be disposed on both sides of the gate electrode GE. The gate spacers GS may include an insulating material.

The gate capping pattern GP may be provided. The gate electrode GE may be provided on the gate capping pattern GP. The gate capping pattern GP may comprise an insulating material.

The active contact AC may be electrically connected to the source/drain patterns SD. The source/drain patterns SD may be electrically connected to the first conductive structure 340 through an active contact AC. The active contact AC may comprise a conductive material.

The first capacitor structure 510 may include a first electrode EL1, a second electrode EL2, and a first capacitor insulating layer CI1. The first electrode EL1 and the second electrode EL2 may be spaced apart from each other. A first capacitor insulating layer CI1 may be interposed between the first electrode EL1 and the second electrode EL2. The first electrode EL1, the second electrode EL2 and the first capacitor insulating layer CI1 of the first capacitor structure 510 may be surrounded by the third insulating structure 530.

The second electrode EL2 of the first capacitor structure 510 may be electrically connected to the source/drain patterns SD through the third conductive structure 540, the second upper pad 560, the first lower pad 360, the first conductive structure 340, and the active contact AC. The first electrode EL1 of the first capacitor structure 510 may be electrically connected to the third conductive structure 540.

The first capacitor structure 510 may store power, and the first logic cell structure 310 may be supplied with a power voltage (e.g., VDD or VSS) from the first capacitor structure 510.

Referring to FIG. 1C, the second logic cell structure 410 may include a fin pattern FP, semiconductor patterns SP, source/drain patterns SD, a gate electrode GE, a gate spacer GS, a gate insulating layer GI, a gate capping pattern GP and an active contact AC.

The structure of the fin pattern FP, the semiconductor patterns SP, the source/drain patterns SD, the gate electrode GE, the gate spacer GS, the gate insulating layer GI, the gate capping pattern GP, and the active contact AC of the second logic cell structure 410 may be similar to the structure of the fin pattern FP, the semiconducting patterns SP, the sources/drain patterns SDS, the gate electrode GE, the gate spacer GS, the gate insulator layer GI, the gateway capping pattern GP and the active contact AC of the first logic cell structure 310.

The fin pattern FP, the semiconductor patterns SP, the source/drain patterns SD, the gate electrode GE, the gate spacer GS, the gate insulating layer GI, the gate capping pattern GP and the active contact AC of the second logic cell structure 410 may be surrounded by the second insulating structure 430.

The second capacitor structure 140 may include a third electrode EL3, a fourth electrode EL4, and a second capacitor insulating layer CI2. The third electrode EL3 and the fourth electrode EL4 may be spaced apart from each other. The second capacitor insulating layer CI2 may be interposed between the third electrode EL3 and the fourth electrode EL4. The second capacitor insulating layer CI2 between the third electrode EL3 and the fourth electrode EL4 may be surrounded by the photosensitive insulating layers 110.

The fourth electrode EL4 of the second capacitor structure 140 may be electrically connected to the source/drain patterns SD through the redistribution pattern 120, the second bump 30, the second lower pad 480, the second conductive structure 440, and the active contact AC. The third electrode EL3 of the second capacitor structure 140 may be electrically connected to the redistribution pattern 120.

The second capacitor structure 140 may store power, and the second logic cell structure 410 may be supplied with a power voltage (e.g., VDD or VSS) from the second capacitor structure 140.

In some implementations, the first logic cell structure 310 powered from the first capacitor structure 510 as the first capacitor structure 510 is disposed within the interposer 500. Accordingly, the power supply path may be relatively short, and the IR drop may be reduced.

In some implementations, as the second capacitor structure 140 is disposed in the base substrate 100, the second logic cell structure 410 may be supplied with power from the second capacitor structure 140. Accordingly, the power supply path may be relatively short, and the IR drop may be reduced. As the first capacitor structure 510 is disposed in the interposer 500 and the second capacitor structure 140 is disposed in the base substrate 100, the semiconductor package according to some implementtions does not need to mount the capacitor structure on the lower surface of the package substrate 1. Accordingly, spaces for forming the terminals 10 may be secured, so that the size of the semiconductor package may be minimized. In addition, cracks generated by the process of mounting the capacitor structure on the package substrate 1 may be reduced.

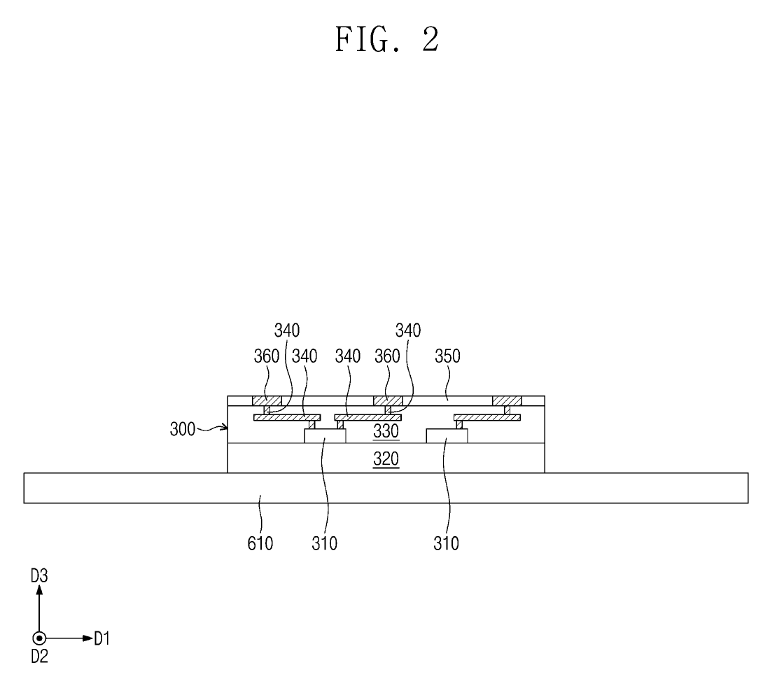

FIGS. 2, 3, 4, 5, 6, 7, 8, and 9 are cross-sectional views illustrating an example of a method of fabricating a semiconductor package according to some implementations.

In FIG. 2, the first chip 300 may be formed on a first carrier substrate 610. Forming the first chip 300 on the first carrier substrate 610 may include forming the first chip 300 and attaching the first chip 300 to the first carrier substrate 610.

Surface treatment of the first chip 300 may be performed. As an example, the first chip 300 may be ground or etched. The surface treatment of the first chip 300 may be a pre-process for performing a hybrid bonding process of the first chip 300.

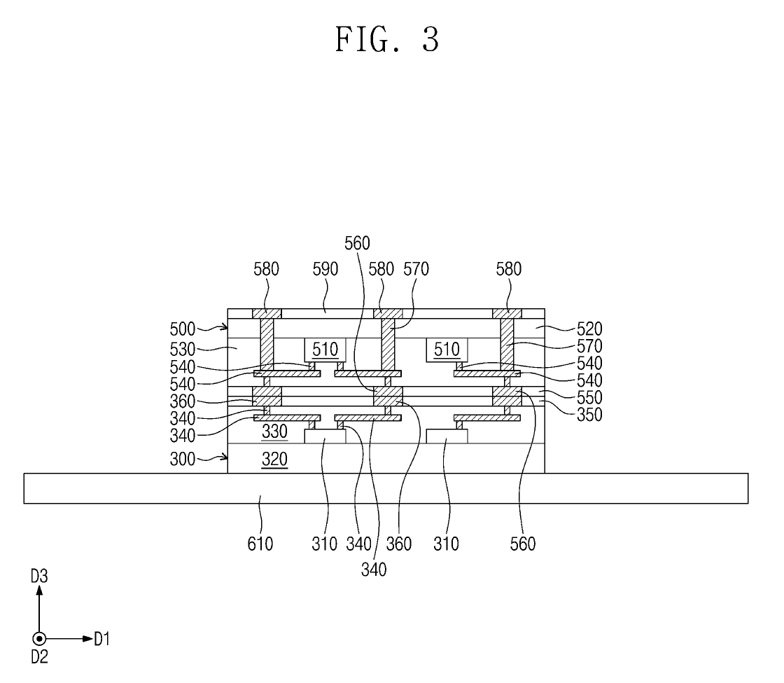

In FIG. 3, the interposer 500 may be disposed on the first chip 300. Disposing the interposer 500 on the first chip 300 may include forming the interposer 500 and hybrid bonding the interposer 500 with the first chip 300.

The second upper pad 560 of the interposer 500 and the first lower pad 360 of the first chip 300 may be bonded, and the second upper insulating layer 550 of the interposer 500 and the first lower insulating layer 350 of the first chip 300 may be bonded.

In some implementations, the interposer 500 may be electrically connected to the first chip 300 using a bump.

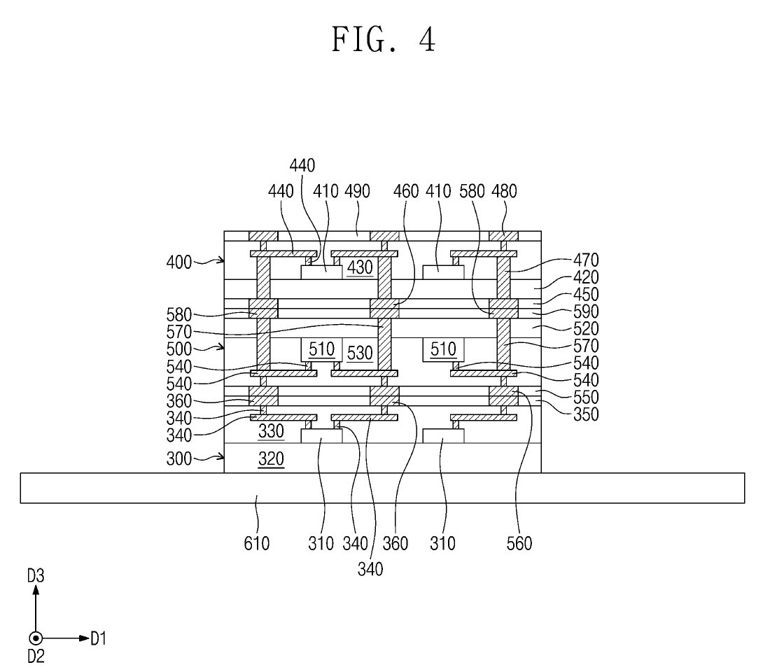

In FIG. 4, the second chip 400 may be disposed on the interposer 500. Disposing the second chip 400 on the interposer 500 may include forming the second chip 400 and hybrid bonding the interposer 500 and the second chip 400.

The third lower pad 580 of the interposer 500 and the first upper pad 460 of the second chip 400 may be bonded, and the third lower insulating layer 590 of the interposers 500 and the first upper insulating layer 450 of the second chip 400 may be bonded.

In some implementations, the second chip 400 may be electrically connected to the interposer 500 using a bump.

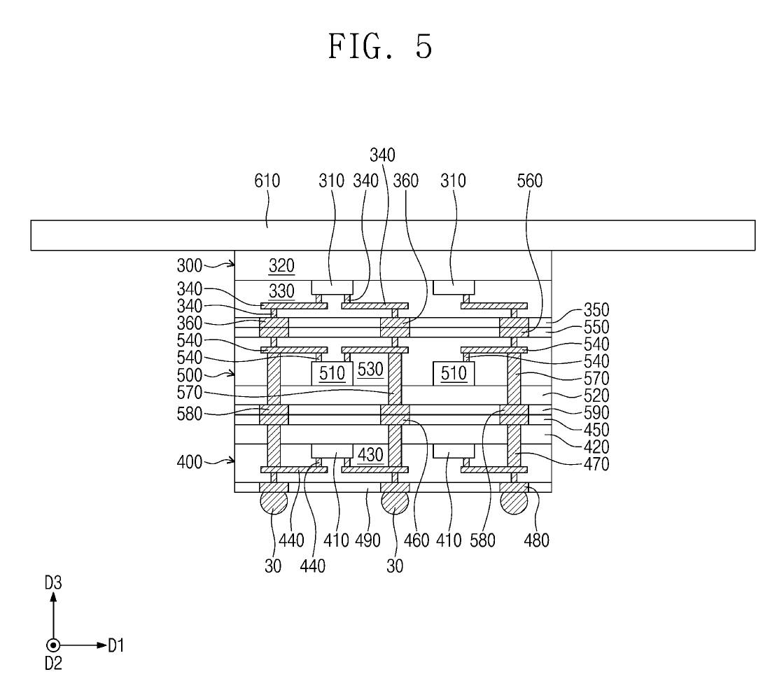

In FIG. 5, the second bump 30 may be formed. The first carrier substrate 610 may be flipped.

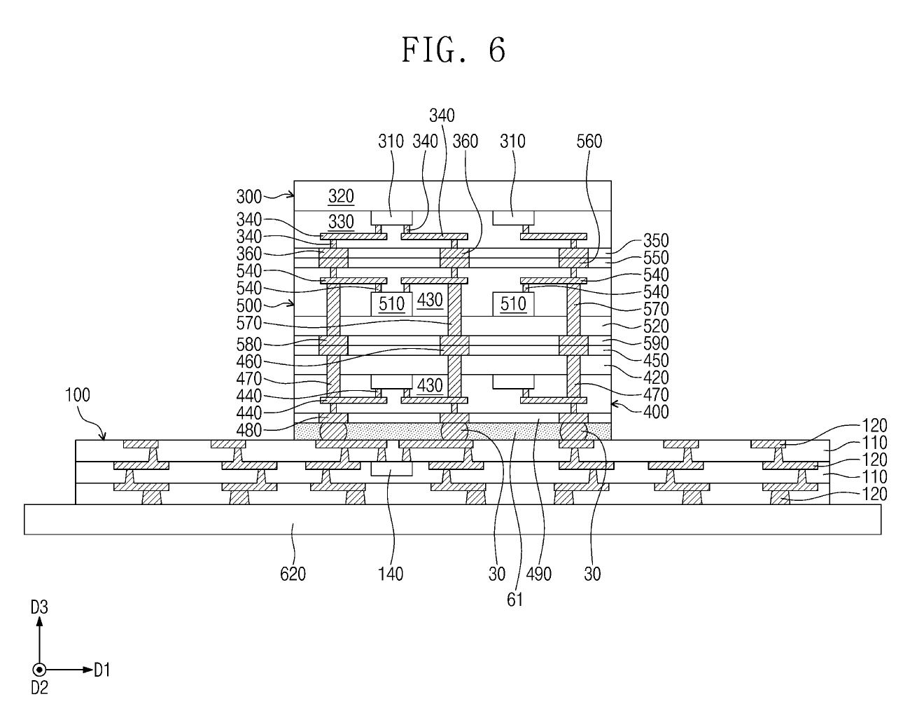

In FIG. 6, the base substrate 100 may be formed on a second carrier substrate 620. The first chip 300, the second chip 400, and the interposer 500 may be mounted on the base substrate 100. Mounting the first chip 300, the second chip 400, and the interposer 500 on the base substrate 100 may include attaching the second bump 30 to the redistribution pattern 120 and forming the second underfill layer 61.

The first carrier substrate 610 may be separated from the first chip 300.

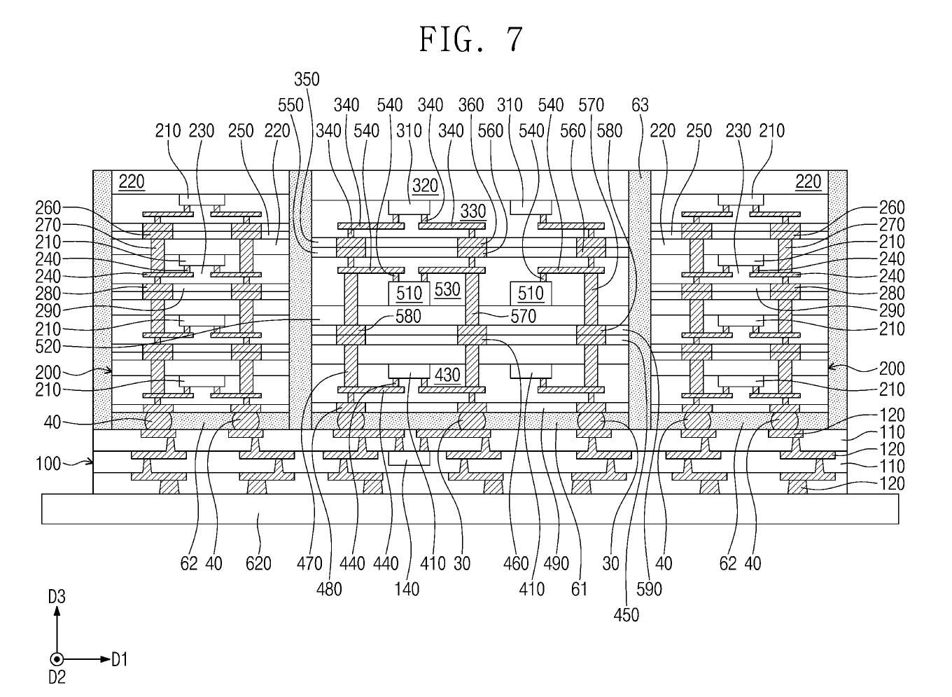

In FIG. 7, memory chips 200 may be mounted on the base substrate 100. The memory chips 200 and the third bumps 40 may be formed, and the third bump 40 may be attached to the redistribution pattern 120. The third underfill layer 62 may be formed.

The molding layer 63 surrounding the memory chips 200, the first chip 300, the second chip 400, and the interposer 500 may be formed.

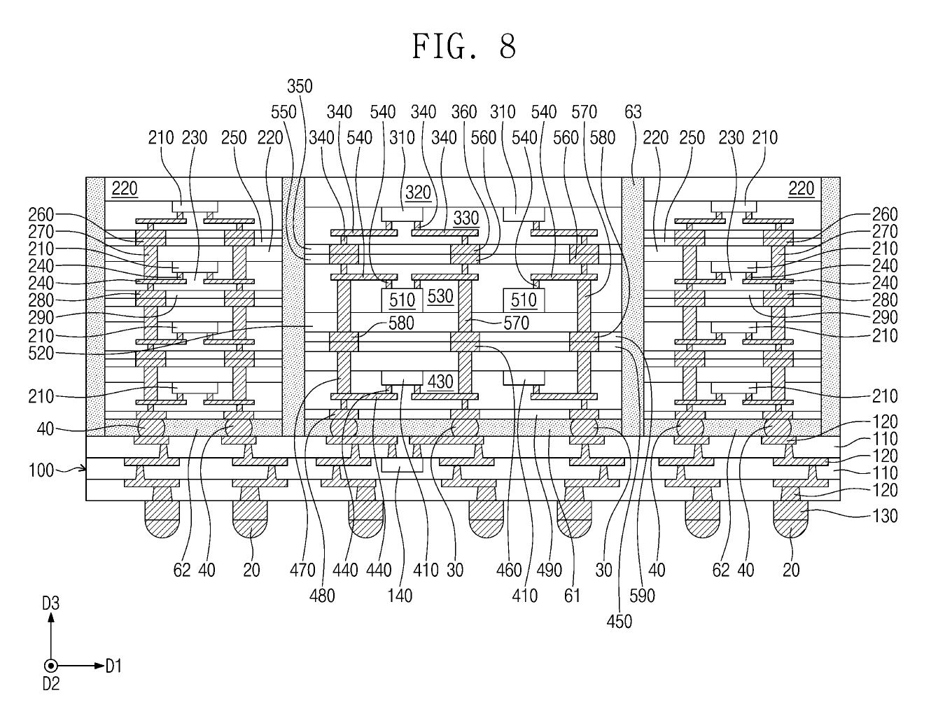

In FIG. 8, the second carrier substrate 620 may be separated from the base substrate 100. The bump connection pattern 130 connected to the redistribution pattern 120 may be formed. The first bump 20 connected to the bump connection pattern 130 may be formed.

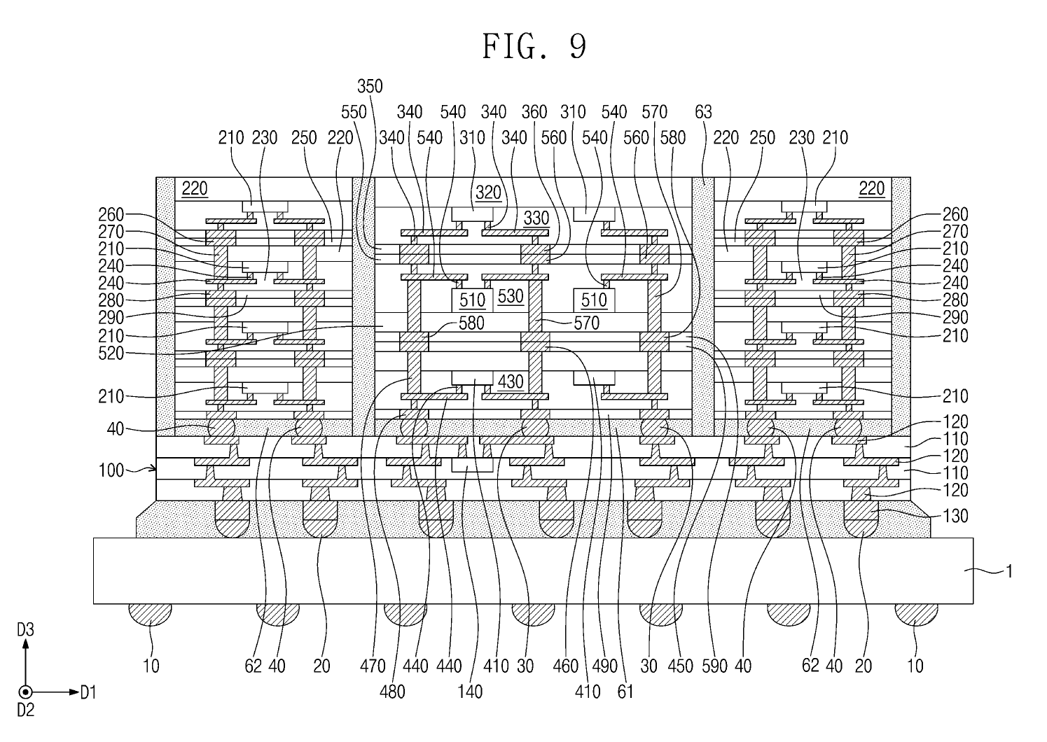

In FIG. 9, the base substrate 100 may be mounted on the package substrate 1. The first bumps 20 may be attached to the package substrate 1. The first underfill layer 50 may be formed.

In FIG. 1A, the heat slug 70 may be formed on the package substrate 1.

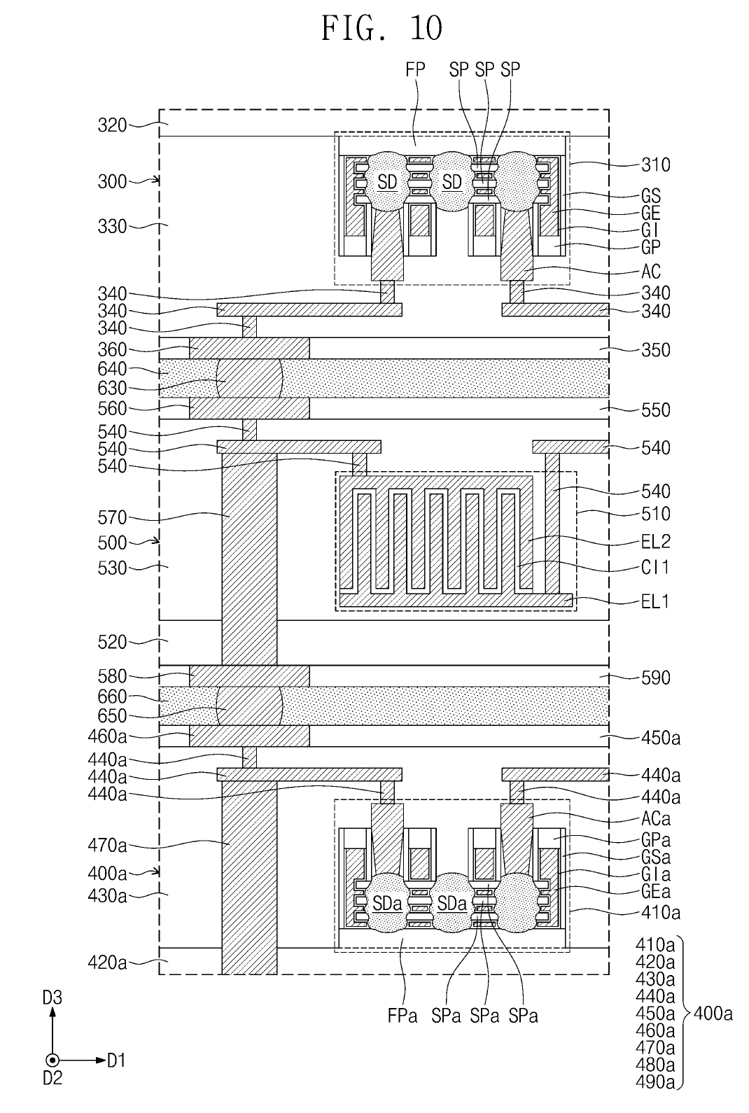

FIG. 10 is an enlarged view of a semiconductor package according to some implementations. The semiconductor package according to FIG. 10 may be similar to the semiconductor package according to FIGS. 1A-1C except as described below.

In FIG. 10, the second chip 400a may include a second substrate 420a, a second insulating structure 430a, a second conductive structure 440a, a first upper insulating layer 450a, a first upper pad 460a, a first through via 470a, a second lower pad 480 (FIG. 1C), a second lower insulating layer 490 (FIG. 1C), and a second logic cell structure 410a.

The second logic cell structure 410a may be disposed on an upper surface of the second substrate 420a. The second insulating structure 430a may be disposed on the upper surface of the second substrate 420a.

The first upper pad 460a may be electrically connected to the second conductive structure 440a. The first upper pad 460a may be in contact with the second conductive structure 440a. The second logic cell structure 410a may be electrically connected to the first upper pad 460a through second conductive structures 440a.

The second logic cell structure 410a may include a fin pattern FPa, semiconductor patterns SPa, source/drain patterns SDa, a gate electrode GEa, a gate spacer GSa, a gate insulating layer GIa, a gate capping pattern GPa, and an active contact ACa.

The fin pattern FPa, the semiconductor patterns SPa, the source/drain patterns SDa, the gate electrode GEa, the gate spacer GSa, the gate insulating layer GIa, the gate capping pattern GPa, and the active contact ACa of the second logic cell structure 410a may be disposed on an upper surface of the second substrate 420a. The fin pattern FP, the semiconductor patterns SP, the source/drain patterns SD, the gate electrode GE, the gate spacer GS, the gate insulating layer GI, the gate capping pattern GP and the active contact AC of the first logic cell structure 310 may be disposed on the lower surface of the first substrate 320.

The first connection bump 630 and the first adhesive layer 640 may be provided between the first chip 300 and the interposer 500. The first connection bump 630 may be in contact with the first lower pad 360 of the first chip 300 and the second upper pad 560 of the interposer 500. The first connection bump 630 may include a conductive material. The first adhesive layer 640 may surround the first connection bump 630. The first adhesive layer 640 may include a polymer material.

The second connection bump 650 and the second adhesive layer 660 may be provided between the second chip 400 and the interposer 500. The second connection bump 650 may be in contact with the first upper pad 460a of the second chip 400 and the third lower pad 580 of the interposer 500. The second connection bump 650 may include a conductive material. The second adhesive layer 660 may surround the second connecting bump 650. The second adhesive layer 660 may include a polymer material.

The first logic cell structure 310 may be electrically connected to the first capacitor structure 510 through the first conductive structures 340, the first lower pad 360, the first connection bump 630, the second upper pad 560, and the third conductive structures 540.

The second logic cell structure 410a may be electrically connected to the first capacitor structure 510 through the second conductive structures 440a, the first upper pad 460a, the second connection bump 650, the third lower pad 580, the second through via 570, and the third conductive structure 540.

The second logic cell structure 410a, the second insulating structure 430a, the second conductive structures 440a, the first upper insulating layer 450a, and the first upper pad 460a may be disposed between the second substrate 420a and the interposer 500.

The first logic cell structure 310 and the second logic cell structure 410a may be supplied with a power voltage from the first capacitor structure 510.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a base substrate; and
a first chip, a second chip, and an interposer that are electrically connected to the base substrate,
wherein the first chip, the second chip, and the interposer overlap with each other,
wherein the interposer is disposed between the first chip and the second chip, and
wherein the interposer comprises a capacitor structure electrically connected to the first chip.

2. The semiconductor package of claim 1,
wherein the first chip comprises a first substrate and a logic cell structure,
wherein the interposer comprises a second substrate, and
wherein the capacitor structure and the logic cell structure are between the first substrate and the second substrate.

3. The semiconductor package of claim 2, wherein the interposer comprises a through via extending into the second substrate.

4. The semiconductor package of claim 2, wherein the logic cell structure comprises:
a source/drain pattern;
a semiconductor pattern connected to the source/drain pattern; and
a gate electrode overlapping the semiconductor pattern.

5. The semiconductor package of claim 2,
wherein the first chip comprises a first insulating structure surrounding the logic cell structure,
wherein the interposer comprises a second insulating structure surrounding the capacitor structure, and
wherein the first insulating structure and the second insulating structure are between the first substrate and the second substrate.

6. The semiconductor package of claim 5,
wherein the first chip comprises:
a lower insulating layer between the first insulating structure and the second insulating structure; and
a lower pad surrounded by the lower insulating layer,
wherein the interposer comprises:
an upper insulating layer between the second insulating structure and the lower insulating layer; and
an upper pad surrounded by the upper insulating layer,
wherein the upper pad and the lower pad contact each other, and
wherein the upper insulating layer and the lower insulating layer contact each other.

7. The semiconductor package of claim 2,
wherein the first chip comprises:
a first conductive structure electrically connected to the logic cell structure; and
a lower pad electrically connected to the first conductive structure,
wherein the interposer comprises:
a second conductive structure electrically connected to the capacitor structure; and
an upper pad electrically connected to the second conductive structure, and
wherein the lower pad and the upper pad are between the first conductive structure and the second conductive structure.

8. A semiconductor package comprising:
a base substrate; and
a first chip, a second chip, and an interposer that are electrically connected to the base substrate,
wherein the first chip, the second chip, and the interposer overlap with each other,
wherein the interposer is between the first chip and the second chip,
wherein the second chip is between the base substrate and the interposer,
wherein the interposer comprises a first substrate and a first capacitor structure, and
wherein the first capacitor structure is between the first substrate and the first chip.

9. The semiconductor package of claim 8, wherein the base substrate comprises a second capacitor structure electrically connected to the second chip.

10. The semiconductor package of claim 9,
wherein the second chip comprises a second substrate and a logic cell structure, and
wherein the logic cell structure is between the second substrate and the second capacitor structure.

11. The semiconductor package of claim 10,
wherein the second chip comprises a through via extending into the second substrate, and
wherein the logic cell structure is electrically connected to the interposer through the through via.

12. The semiconductor package of claim 9, wherein the base substrate comprises:
photosensitive insulating layers surrounding the second capacitor structure; and
a redistribution pattern in the photosensitive insulating layers.

13. The semiconductor package of claim 8,
wherein the first chip comprises a second substrate and a first logic cell structure,
wherein the second chip comprises a third substrate and a second logic cell structure,
wherein the first logic cell structure is between the second substrate and the interposer, and
wherein the second logic cell structure is between the third substrate and the interposer.

14. The semiconductor package of claim 13, wherein the first logic cell structure and the second logic cell structure are electrically connected to the first capacitor structure.

15. The semiconductor package of claim 13,
wherein the interposer comprises a through via extending into the first substrate, and
wherein the second logic cell structure is electrically connected to the first capacitor structure through the through via.

16. A semiconductor package comprising:
a package substrate;
a base substrate electrically connected to the package substrate; and
a first chip, a second chip, an interposer, first memory chips, and second memory chips that are electrically connected to the base substrate,
wherein the first chip, the second chip, and the interposer overlap with each other,
wherein the first memory chips overlap with each other,
wherein the second memory chips overlap with each other,
wherein the interposer is between the first chip and the second chip,
wherein the first chip, the second chip, and the interposer are between the first memory chips and the second memory chips,
wherein the interposer comprises a substrate and a through via extending into the substrate,
wherein the first chip comprises a first logic cell structure,
wherein the second chip comprises a second logic cell structure, and
wherein the through via electrically connects the first chip and the second chip.

17. The semiconductor package of claim 16, wherein the interposer comprises a capacitor structure electrically connected to the first logic cell structure.

18. The semiconductor package of claim 16,
wherein the first chip comprises a first lower pad,
wherein the interposer comprises a first upper pad,
wherein the first lower pad contacts the first upper pad, and
wherein the first logic cell structure is electrically connected to a capacitor structure through the first lower pad and the first upper pad.

19. The semiconductor package of claim 18,
wherein the interposer comprises a second lower pad,
wherein the second chip comprises a second upper pad, and
wherein the second lower pad contacts the second upper pad.

20. The semiconductor package of claim 17, wherein the second logic cell structure is electrically connected to the capacitor structure.
